(19) United States
(12) Patent Application Publication
(10) Pub. No.: US 2014/0120293 A1
(43) Pub. Date: May 1, 2014

(54) ELECTROSTATIC DISCHARGE COMPATIBLE DICING TAPE WITH LASER SCRIBE CAPABILITY

(71) Applicants: Mohit Gupta, Chandler, AZ (US); Haiwei Lu, Chandler, AZ (US); Dingying D. Xu, Maricopa, AZ (US); Ninad Patel, Chandler, AZ (US); Kowtilya Bijjula, Chandler, AZ (US); P. Erasenthiran Poonjolai, Chandler, AZ (US)

(72) Inventors: Mohit Gupta, Chandler, AZ (US); Haiwei Lu, Chandler, AZ (US); Dingying D. Xu, Maricopa, AZ (US); Ninad Patel, Chandler, AZ (US); Kowtilya Bijjula, Chandler, AZ (US); P. Erasenthiran Poonjolai, Chandler, AZ (US)

(21) Appl. No.: 13/993,336

(22) PCT Filed: Dec. 22, 2011
(86) PCT No.: PCT/US11/66901

§ 371 Date: Sep. 18, 2013

(51) Int. Cl. H01L 21/683

(52) U.S. Cl. CPC H01L 21/6836
USPC 428/41.7; 428/354

(57) ABSTRACT

The present disclosure relates to the field of fabricating microelectronic devices, wherein a microelectronic device substrate, such as a microelectronic wafer, may be diced into individual microelectronic dice using an adhesive tape which reduces the potential of electrostatic discharge damage by the incorporation or anti-static, and may be compatible with a laser scribing process by the incorporation of ultraviolet light absorbing agents into an adhesive layer of the adhesive tape.

### BACKGROUND

Embodiments of the present description generally relate to the field of microelectronic device fabrication and more particularly, to the dicing of microelectronic device wafers into individual microelectronic dice.

BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings, It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

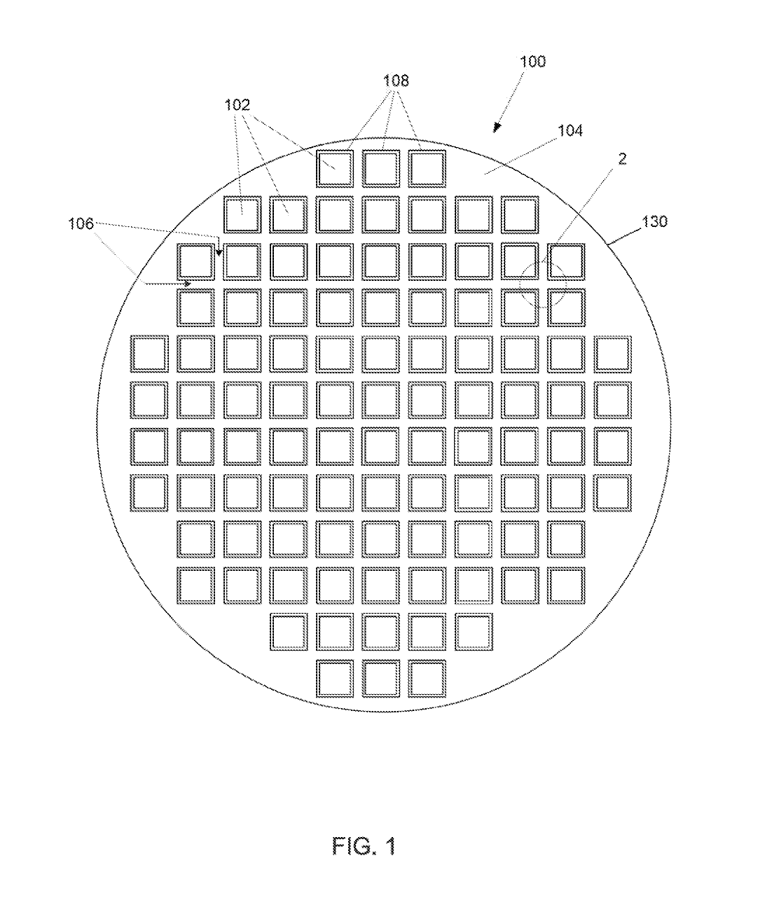

FIG. 1 illustrates a microelectronic device substrate having a plurality of microelectronic dice on an active surface thereof.

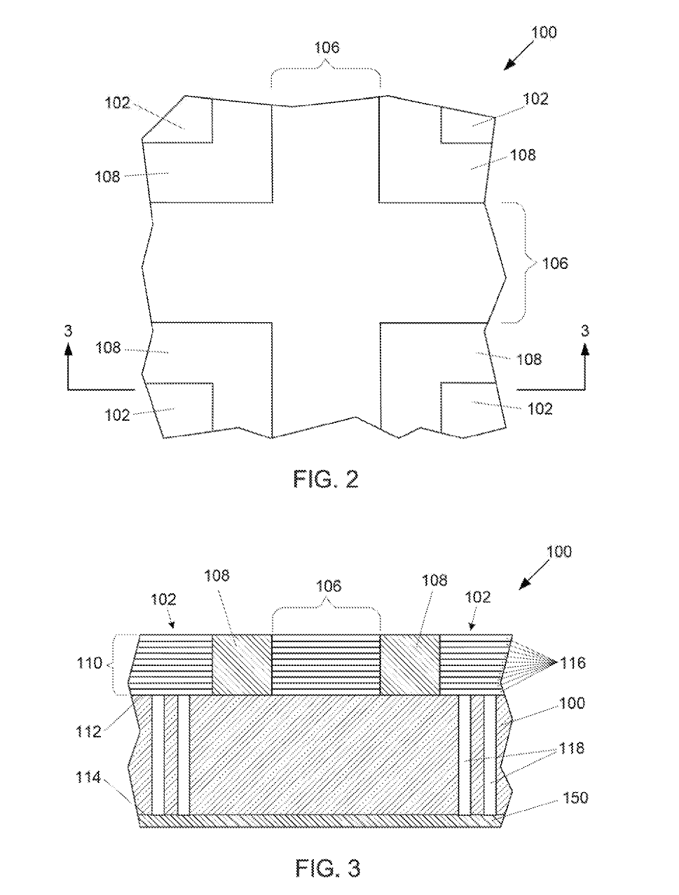

FIG. 2 is a top plan close-up view of insert 2 of FIG. 1 showing the dicing street areas.

FIG. 3 is a side cross-sectional view of the dicing street areas of a microelectronic device wafer along line 3-3 of FIG. 2;

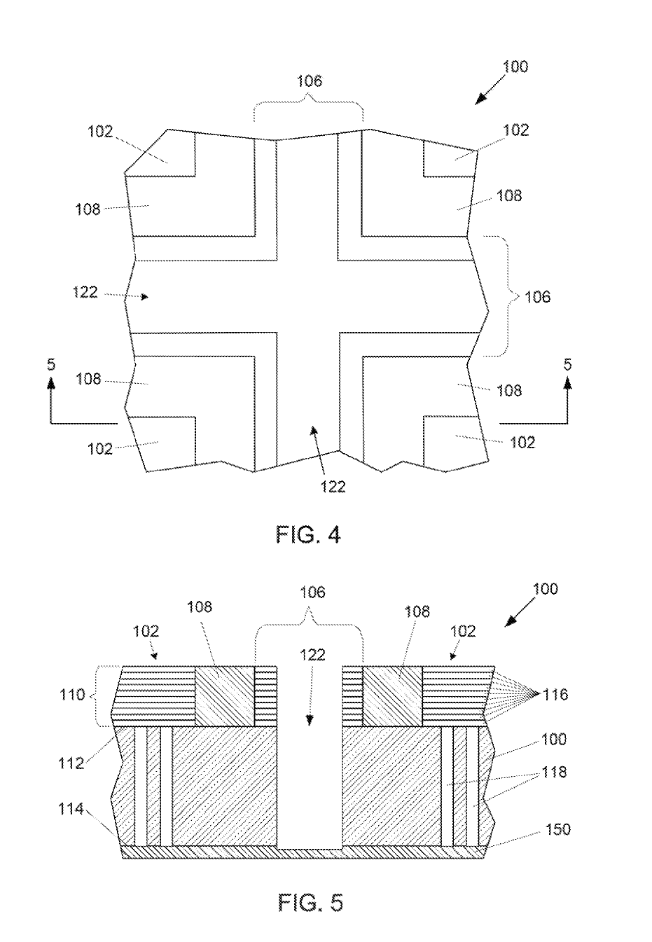

FIG. 4 is a top plan close-up view of the microelectronic device wafer after dicing;

FIG. 5 is a side cross-sectional view of the dicing street areas of a microelectronic device wafer along line 5-5 of FIG. 4;

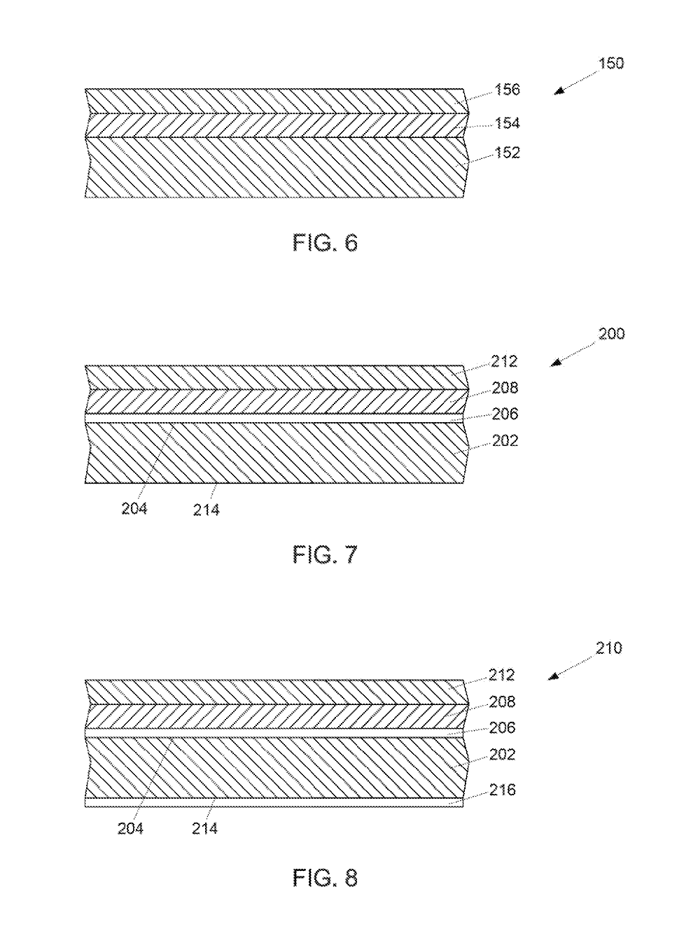

FIG. 6 illustrates a side cross-sectional view of an adhesive tape according to an embodiment of the present description.

FIG. 7 illustrates a side cross-sectional view of an adhesive tape, according to an embodiment of the present description.

FIG. 8 illustrates a side cross-sectional view of an adhesive tape, according to another embodiment of the present description.

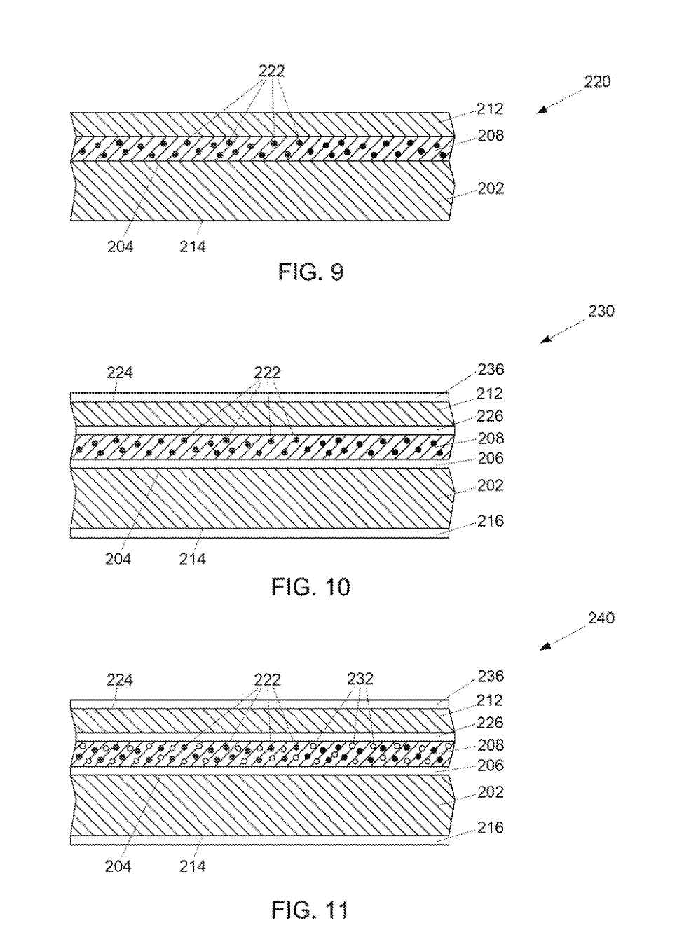

FIG. 9 illustrates a side cross-sectional view of an adhesive tape, according to yet another embodiment of the present description.

FIG. 10 illustrates a side cross-sectional view of an adhesive tape, according to still another embodiment of the present description.

FIG. 11 illustrates a side. cross-sectional view of an adhesive tape, according to yet still another embodiment of the present description.

### DETAILED DESCRIPTION

In the following detailed description, reference is made to the accompanying drawings that show, by way of illustration, specific embodiments m which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description relate to the field of fabricating microelectronic devices, wherein a microelectronic device substrate, such as a microelectronic wafer, may be diced into individual microelectronic dice using an adhesive tape which reduces the potential of electrostatic discharge damage and may be compatible with a laser scribing process.

In the production of microelectronic devices, integrated circuitry may be formed in and/or on microelectronic device wafers. As shown in FIG. 1, a single microelectronic device wafer 100, such as a silicon, silicon-on-insulator, gallium arsenide, or a silicon-germanium wafer, may contain a plurality of substantially identical integrated circuits (not shown) forming a plurality of microelectronic dice 102, such as microprocessors, chipsets, graphics devices, wireless devices, memory devices, application, specific integrated circuits, or the like, on an active surface 104 of the microelectronic device wafer 100, which are usually substantially rectangular and arranged in rows and columns. It is, of course, understood that the use of the term “wafer” does not only include an entire wafer, but also includes portions thereof

In general, two sets of mutually parallel dicing streets 106 may extend perpendicular to each other over substantially the entire microelectronic device wafer active surface 104 between each discrete microelectronic die 102. It is understood that the integrated circuitry of each microelectronic die 102 may be any circuit components, electrical connections, or combinations thereof, including but not limited to transistors, resistors, capacitors, conductive traces, and the like, which may form a microprocessor, a chipset, a memory device, an ASIC, and the like. As shown in FIGS. 1 and 2, the microelectronic device wafer 100 may have at least one interconnect guard ring 108, each of which substantially surrounds each microelectronic die 102, thereby isolating the integrated circuit (not shown) of each microelectronic die 102 from the dicing streets 106.

As shown in FIG. 3, the microelectronic device wafer 100 may comprise an interconnect layer 110 disposed on a first surface 112 and may be mounted by a second surface 114 thereof to a sticky, flexible adhesive tape 150. The interconnect layer 110 may provide routes for electrical communication between integrated circuit components within the microelectronic dice 102, as well as to external interconnects not shown), as will be understood by those skilled in the art. The interconnect layer 110 is generally alternating layers 116 of dielectric material, including but not limited to silicon dioxide, silicon nitride, epoxy resin, polyimide, bisbenzocyclobutene, fluorinated silicon dioxide, carbon-doped silicon dioxide, silicon carbide, various polymeric dielectric materials, and the like, and patterned electrically conductive material, including copper, aluminum, silver, titanium, alloys thereof, and the like. The methods and processes for fabricating the interconnect layer 110 as well as the minor constituent materials in the various layer thereof will be evident to those skilled in the art. The interconnect guard ring 108 may be formed layer by layer as the interconnect layer 110 is formed and may be formed of stacked metal layers. The interconnect guard ring 108 may assist in preventing external contamination encroaching into the microelectronic dice 102 through delamination and/or cracks caused by the subsequent dicing of the microelectronic device wafer 100.

As also shown in FIG. 3, the microelectronic device wafer 100 may comprise at least one through-silicon via 118 extending from microelectronic device wafer first surface 112 to microelectronic device wafer second surface 114. Through-silicon vias 118 are conductive paths that may be used for signal transmission between stacked individual microelectronic dice 102 in the formation of microelectronic packages (not shown). The through-silicon vias 118 may be fabricated by forming an opening through the microelectronic device wafer 100, such as by etching, laser drilling, ion drilling, and the like, and disposing an electrically conductive material, such as copper, aluminum silver, titanium, alloys thereof, and the like, therein, such as by plating, deposition, and the like.

Within the dicing streets 106, there may be test structures (not shown) that are composed of the same materials as the other parts of the interconnect layer 110. Between these test structures in the dicing street 106 and the interconnect guard ring 108 may be a region or regions composed entirely of dielectric material with no conductive material between the layers 116.

After the microelectronic die 102 on the microelectronic device wafer 100 have been subjected to preliminary testing for functionality (wafer sort), the microelectronic device wafer 100 may be diced (cut apart), so that each area of functioning microelectronic die 102 becomes a microelectronic die (not shown) that can be used to form a packaged microelectronic device (not shown). As previously discussed, prior to dicing, the microelectronic device wafer 100 may be mounted onto the sticky, flexible adhesive tape 150 by its second surface 114. The adhesive tape 150 may be attached to a ridge frame (not shown). The adhesive tape 150 may continue to hold the diced (singulated) microelectronic die 102 after the dicing operation and daring transport to the subsequent assembly steps.

As shown in FIGS. 4 and 5, channels 122 may be cut down perpendicular sets of the dicing streets 106 lying between each of the rows and columns (see FIG. 1), through the interconnect layer 110 and the microelectronic device water 100. The channels 122 may be cut using a laser (referred. to as laser scribing), with a saw (not shown), such as a circular diamond-impregnated dicing saw, or combinations of laser scribing and sawing. Of course, the dicing streets 106 are sized to allow for the formation of the channels 122 between adjacent microelectronic dice 102 without causing damage to the microelectronic dice 102. Once the dicing of the microelectronic device wafer 100 is complete, the individual microelectronic dice 102 are removed from the adhesive tape 150.

As shown in FIG. 6, the adhesive tape 150 may be supplied as a base film 152 having an adhesive layer 154 disposed thereon with a protective liner layer 156 laminated on the adhesive layer 154. During a tape lamination process, the protective liner layer 156 is peeled away to exposed the adhesive layer 154 and the microelectronic device wafer second surface 114 (see FIG. 3) is attached to the base film 152 with the adhesive layer 154. However, peeling of the protective liner layer 156 may generate an electrostatic charge within the adhesive tape 150, as high as 2-5 kilovolts. Furthermore, the process of removing the individual microelectronic dice 102 from the adhesive tape 50, generally using a collet and an ejector, may also generate an electrostatic charge within the adhesive tape 150, as high as 1000 volts. If this electrostatic charge discharges through the microelectronic device wafer 100, the discharge can damage the integrated circuits and/or interconnect layer 108 of their respective microelectronic dice 102 (see FIG. 1), as will be understood those skilled in the art. This discharge damage may be exacerbated by the presence of the through-silicon vias 118 extending through the microelectronic device wafer 100.

In an embodiment of the present disclosure of FIG. 7, an adhesive tape 200 may be comprised of a base film 202, it first anti-static. layer 206 on a first surface 204 of the base film 202, and an adhesive layer 208 on the first anti-static layer 206. A protective liner material 212 may be placed against the adhesive layer 208. The adhesive layer 208 may be any appropriate material, including but not limited to, ultraviolet curable materials. For relatively thin microelectronic device wafers 100 using an ultraviolet light curable adhesive layer 208 may help in microelectronic device wafer 100 handling during microelectronic die 102 fabrications processes, where the ultraviolet light curable adhesive layer 208 may have high adhesion strength before ultraviolet: light: curing which is required during laser scribing, sawing, and the like, and may have low adhesion strength after ultraviolet light exposure/curing which may be required during subsequent processing. In one embodiment, the base film 202 may be optically transparent to allow for the inspection of the microelectronic device wafer second surface 114. The base film 202 may further have appropriate elastic properties such as balanced stiffness and elongation of stability during dicing and the removal of the diced microelectronic dice 102 from the adhesive tape 200.

In one embodiment. the first anti-static layer 206 may comprise an electrically conductive material, including but not limited to conducting polymers (such as polyaniline, polypyrole, poly polyacetylene, polyphenylene vinylene, poly 3,4,-ethylenedioxythiophene, polyphenylene sulfide, and the like) and conductive metal oxides (such as indium tin oxide and the like), as a mechanism for electrostatic discharge. As will be understood to those skilled in the art, the electrically conductive element may be grounded such that any electrostatic charge that maybe built-up during the attachment of the adhesive tape 200 to the microelectronic device wafer 100 and/or during the removing the individual microelectronic dice 102 from the adhesive tape 200 may be discharged.

In another embodiment, the first anti-static, layer 206 may comprise a thin layer of anti-static: material, including but not limited to interfacial active agents or surfactants, such as ammonium or phosphate salts, quaternary ammonium salts, phosphate esters, polyethylene glycol esters, and the like, as a mechanism to render the adhesive tape 200 substantially statically dissipative. In one embodiment, the and-static material may reduce surface resistance values between about 10⁵ and 10¹⁰ Ω. As will be understood to those skilled in the art, the anti-static layer 206 may substantially reduce or substantially prevent to generation of an electrostatic charge during the attachment of the adhesive tape 200 to the microelectronic device wafer 100 and/or during the removing the individual microelectronic dice 102 from the adhesive tape 200. The anti-static layer 206 may also allow for rapid. discharge for any electrostatic charge which may build-up.

In another embodiment of the present disclosure of FIG. 8, an adhesive tape 210 may be comprised of the base film 202, the first anti-static layer 206 on the base film first surface 204, a second anti-static layer 216 on an opposing second surface 214 of the base film 202, and the adhesive layer 208 on the first antistatic layer 206. The protective liner material 212 may be placed against the adhesive layer 208.

In still another embodiment of the present disclosure of FIG. 9, an adhesive tape 220 may be comprised of the base film 202 and the adhesive layer 208, wherein the adhesive layer 208 contains an anti-static agent (illustrated as black circles, elements 222) dispersed therein. The anti-static agent may comprise any appropriate anti-static agent for a mechanism to render the adhesive tape 220 substantially statically dissipative. In one embodiment, the anti-static agent may be a conducting polymer, including, but not limited to polyaniline, polypyrole, polythiophene, polyacetylene, polypbenylene vinylene, and the like. In another embodiment, the anti-static agent may be a surfactants, including but not limited to ammonium salts, phosphate salts, quaternary ammonium salts, phosphate esters, polyethylene glycol esters, long-chain aliphatic amines (optionally ethoxylated), and the like), and ionic liquids. In still another embodiment, the anti-static agent may comprise conductive fillers, including but not limited to metal coated glass, aluminum doped zinc oxide, nickel-coated graphite, indium tin oxide, silver particles, tin particles, and the like. The protective liner material 212 may be placed against the adhesive layer 208.

It is understood that further embodiments of the present disclosure may include various combination of anti-static agents within the adhesive layer and/or antistatic layers. As shown in FIG. 10, an adhesive tape 230 may be comprised of the base film 202, the first anti-static layer 206 on the base film first surface 204, the second anti-static layer 216 on the base film second surface 214, and the adhesive layer 208 on the first antistatic layer 206, wherein the adhesive layer 208 may contain the anti-static agent 222, The protective liner material 212 may be placed against the adhesive layer 208 wherein a third anti-static layer 226 may deposed between the protective liner material 212 and the adhesive layer 208 and wherein a fourth anti-static layer 236 may be disposed On an exterior surface 224 (opposite the third anti-static layer 226) of the protective liner material 212. Of course any of the various anti-static agents within the adhesive layer and/or anti-static layers may be included or excluded.

In the use of lasers, the base film 202 may be damaged if the laser strikes it directly during a laser scribing process. This situation is becoming more likely as microelectronic dice 102 are formed closer to an edge 130 (see FIG. 1) of the microelectronic device wafer 100 in order to increase the number of microelectronic dice 102 formed per microelectronic device wafer 100. As will be understood, the window of allowable undertravel of the scribing laser becomes narrow and the risk of overtravel increases. Overtravel can result in the laser punching through the base film 202, which increases the risk of chuck table damage and the risk of delamination from the adhesive tape (such as elements 150, 200, 210, and 230).

In one embodiment of the present description illustrated in FIG. 11, an ultraviolet light absorbing agent 232 (shown as white circles) may be dispersed within the adhesive layer 208. The ultraviolet light absorbing agent 232 may comprise any appropriate ultraviolet light absorbing agent 232, including but not limited to Univul® (available from BASF Corporation 100 Campus Drive Florham Park, N.J., USA), benzophenone, titanium dioxide, p-aminobenzoate, and the like. It is understood that the ultraviolet light absorbing agent 232 may be incorporated into the adhesive layer 208 as a part of any of the various combinations of anti-static agents within the adhesive layer and/or antistatic layers. As shown in FIG. 11, an adhesive tape 240 may be comprised of the base film 202, the first anti-static layer 206 on the base film first surface 204, the second anti-static layer 216 on an opposing second surface 214 of the base film 202, and the adhesive layer 208 on the first antistatic layer 206, wherein the adhesive layer 208 contains the anti-static agent 222 and/or the ultraviolet light absorbing agent 232. The protective liner material 212 may be placed against the adhesive layer 208 wherein the third anti-static layer 226 may deposed between the protective liner material 212 and the adhesive layer 208 and wherein the fourth anti-static layer 236 may be disposed on the protective liner material exterior surface 224. Of course, any of the various anti-static agents within the adhesive layer and/or anti-static layers may be included or excluded.

It is understood that the subject matter of the present description is not necessarily limited to specific applications illustrated in FIGS. 1-11. The subject matter may be applied to other microelectronic device fabrication applications, as will be understood to those skilled in the art. Furthermore, the subject matter may also be used in any appropriate application outside of the microelectronic device fabrication field.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An adhesive tape comprising:
a base film:
an adhesive layer disposed proximate a first surface of the base film; and
at least one anti-static layer proximate the base film.

2. The adhesive tape of claim 1, wherein the at least one anti-static layer is selected from the group consisting of conducting polymers, surfactants, and conductive metal oxides.

3. The adhesive tape of claim 1, wherein the at least one anti-static layer comprises an anti-static layer disposed between the base film and the adhesive layer.

4. The adhesive tape of claim 3, further including an anti-static layer disposed on a second surface of the base film.

5. The adhesive tape of claim 1, wherein the base film is optically transparent.

6. The adhesive tape of claim 1, further including a protective liner layer disposed on the adhesive layer.

7. The adhesive tape of claim 6, further include an anti-static layer disposed between the adhesive layer and the protective liner material.

8. The adhesive tape of claim 6, further including an anti-static layer disposed on an external surface of the protective liner material.

9. An adhesive tape comprising:
a base film;
an adhesive layer disposed proximate a first surface of the base film, and
an anti-static agent dispersed within the adhesive layer.

10. The adhesive tape of claim 9, wherein the anti-static layer is selected from the group consisting of conducting polymers, surfactants, and conductive metal-oxides.

11. The adhesive tape of claim 9, further include at least one anti-static layer disposed on at least one of the base film first surface and a second surface of the base film.

12. The adhesive tape of claim 9, wherein the base film is optically transparent

13. The adhesive tape of claim 9, further including a protective liner layer disposed on the adhesive layer.

14. The adhesive tape of claim 13, further including an anti-static layer disposed between the adhesive layer and the protective liner material.

15. The adhesive tape of claim 13, further including an anti-static layer disposed on an external surface of the protective liner material.

16. An adhesive tape comprising:
a base film;
an adhesive layer disposed proximate a first surface of the base film including an anti-static agent dispersed therein: and
at least one anti-static layer proximate the base film.

17. The adhesive tape of claim 16. wherein the at least one anti-static layer is selected from the group consisting of conducting polymers, surfactants, and conductive metal oxides.

18. The adhesive tape of claim 16, wherein the at least one anti-static layer comprises an anti-static layer disposed between the base film and the adhesive layer.

19. The adhesive tape of claim 18, further including an anti-static layer disposed on a second surface of the base film.

20. The adhesive tape of claim 16, wherein the base film is optically transparent.

21. The adhesive tape of claim 16, further including a protective liner layer disposed on the adhesive layer.

22. The adhesive tape of claim 21, further include an anti-static layer disposed between the adhesive layer and the protective liner material.

23. The adhesive tape of claim 21, farther including an anti-static layer disposed on an external surface of the protective liner material.

24. An adhesive tape comprising:
a base film;
an adhesive layer disposed proximate a first surface of the base film; and
an anti-static agent dispersed within the adhesive layer.
at least one anti-static layer.

25. The adhesive tape of claim 24, wherein the anti-static agent is selected from the group consisting of conducting polymers, surfactants, and conductive metal oxides.

26. The adhesive tape of claim 24, further include at least one anti-static layer disposed on at least one of the base film first surface and a second surface of the base film.

27. The adhesive tape of claim 24, wherein the base film is optically transparent.

28. The adhesive tape of claim 24, further including a protective liner layer disposed on the adhesive layer.

29. The adhesive tape of claim 28, further including an anti-static layer disposed between the adhesive layer and the protective liner material.

30. The adhesive tape of claim 28, further including an anti-static layer disposed on an external surface of the protective finer material.
